(19) United States
(12) Patent Application Publication
(10) Pub. No.: US 2021/0098315 A1
(43) Pub. Date: Apr. 1, 2021

(54) METHOD FOR CURING SOLID STATE PHOTOSENSORS

(71) Applicant: Applied Materials Israel Ltd., Rehovot (IL)

(72) Inventor: Pavel Margulis, Ashdod (IL)

(73) Assignee: Applied Materials Israel Ltd., Rehovot (IL)

(21) Appl. No.: 16/583,627

(22) Filed: Sep. 26, 2019

(51) Int. Cl. H01L 21/66; H01L 21/67; H01L 31/105; H01L 31/107; H01L 31/18

(52) U.S. Cl. CPC H01L 22/26; H01L 21/67248; H01L 21/67103; H01L 31/107; H01L 31/186; H01L 31/105

(57) ABSTRACT

A detection circuit that may include a solid state photosensor that may include a junction, a controller, and a measurement circuit. The measurement circuit is configured to generate a measurement result that is indicative of a temperature of the junction during a curing period of the solid state photosensor. The controller is configured to control, during the curing period, the temperature of the junction, based on the measurement result.

### BACKGROUND

Solid state photo sensors experience degradation of performance after long time exposure to the flux of energetic particles, which bring significant energy to the lattice of the photo-sensor crystal. It is applicable for example to the beam of particles, like electrons, protons, radiation photons—UV light, X-ray, alpha, betta, gamma particles, etc.

The mechanism of such performance degradation is usually a damage of the lattice by ionizing some atoms and as results making a charge traps. Such performance degradation usually is localized in the radiation absorption layer, which is located close to the device semiconductor junction.

There is a growing need to cure solid state photosensors.

### SUMMARY

There may be provided a detection circuit that may include a solid state photosensor that may include a junction, a controller, and a measurement circuit. The measurement circuit is configured to generate a measurement result that is indicative of a temperature of the junction during a curing period of the solid state photosensor. The controller is configured to control, during the curing period, the temperature of the junction, based on the measurement result.

There may be provided a method for curing a solid state photosensor, the method may include generating, by a measurement circuit, a measurement result that is indicative of a temperature of a junction of the solid state photosensor, during a curing period of the solid state photosensor; and controlling, by a controller and during the curing period, a temperature of the junction, based on the measurement result.

### BRIEF DESCRIPTION OF THE DRAWINGS

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings in which:

FIG. 1A illustrates an example of a detection circuit;

FIG. 1B illustrates an example of a detection circuit;

FIG. 2 illustrates an example of a PIN diode of the detection circuit;

FIG. 3 illustrates an example of an avalanche photodiode of the detection circuit; and

FIG. 4 illustrates an example of a method.

### DETAILED DESCRIPTION

In the following detailed description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using electronic components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure

Any reference in the specification to a method should be applied mutatis mutandis to a system capable of executing the method and should be applied mutatis mutandis to a computer readable medium that is non-transitory and stores instructions for executing the method.

Any reference in the specification to a system should be applied mutatis mutandis to a method that may be executed by the system and should be applied mutatis mutandis to a computer readable medium that is non-transitory and stores instructions executable by the system.

Any reference in the specification to a computer readable medium that is non-transitory should be applied mutatis mutandis to a method that may be applied when executing instructions stored in the computer readable medium and should be applied mutatis mutandis to a system configured to execute the instructions stored in the computer readable medium.

The term “and/or” means additionally or alternatively.

There may be provided a device that that may include a solid state photosensor that may include a junction, a controller, and a measurement circuit. There may be provided a method for curing the solid state photosensor.

The solid state photosensor may belong to a measurement system. The curing of the solid state photosensor can be done without extracting the solid state photosensor from the measurement system. This may prolong the lifespan of the solid state sensor, and reduce the complexity of the curing.

The device can be made of materials that withstand the heating. Alternatively, at least a heated part of the device is made of materials that withstand the heating.

The curing may include heating the solid state photosensor during one or more curing periods. The duration of a curing period may be fixed, or may require heating the solid state photosensor to a certain temperature during a certain time period.

The heating eliminates charge traps in a lattice of the solid-state semiconductor material, which will result in recovering of one or more degraded properties of the solid state photosensor.

The recovered properties may include at least one out of photo-sensitivity, quantum efficiency, signal to noise ratio, and leakage current level.

The measurement circuit may be configured to generate a measurement result that is indicative of a temperature of the junction during a curing period of the solid state photosensor.

The controller may be configured to control, during the curing period, the temperature of the junction, based on the measurement result.

The junction may be heated during the curing period and the controller may control the heating process.

Non-limiting examples of manner of heating the junction may include at least one of the following:
a. Illuminating the solid state photosensor while the solid state photosensor is reverse biased. The solid state photosensor converts the illumination to a photo-current that flows through the junction and heats the junction.
b. Flowing, through the junction and while the solid state photosensor is forward biased, by a bias forward current having a given value. The bias forward current heats the solid state photosensor.
c. Heating the junction using a heating element (for example temperature controlling element 70) that is thermally coupled to the solid state photosensor.

The controller may control each of said heating processes.

The controller may be configured to control the temperature of the junction by controlling an illuminating of the junction, by an illumination source, during the curing period.

The controller may be configured to control the temperature of the junction by controlling a flow of forward current through the junction.

The controller may be configured to control the temperature of the junction by controlling a temperature controlling element (such as but not limited to that is thermally coupled to the solid state photosensor).

The measurement circuit may be configured to (a) measure a forward junction voltage developed over the junction during the curing period, and (b) determine the measurement result based on the forward junction voltage. This measurement circuit may include a voltmeter and/or a current meter, and the like.

The measurement circuit may be configured to (a) measure heat radiation emitted from the solid state photosensor, and (b) determine the measurement result based on the heat radiation. This measurement circuit may include a heat sensor.

The measurement circuit may be configured to (a) measure, during the curing period, a temperature related parameter of a temperature sensitive component that is thermally coupled to the solid state photosensor, and (b) determine the measurement result based on the temperature related parameter. This measurement circuit may include a voltmeter and/or a current meter, and/or a heat sensor, and the like.

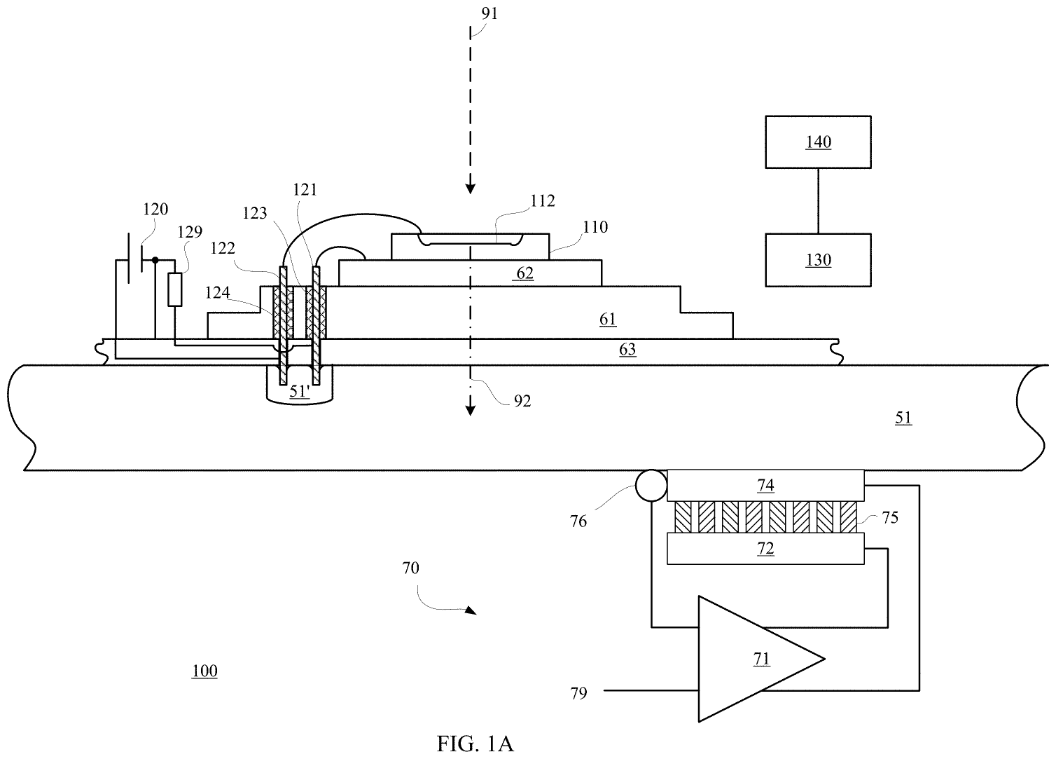

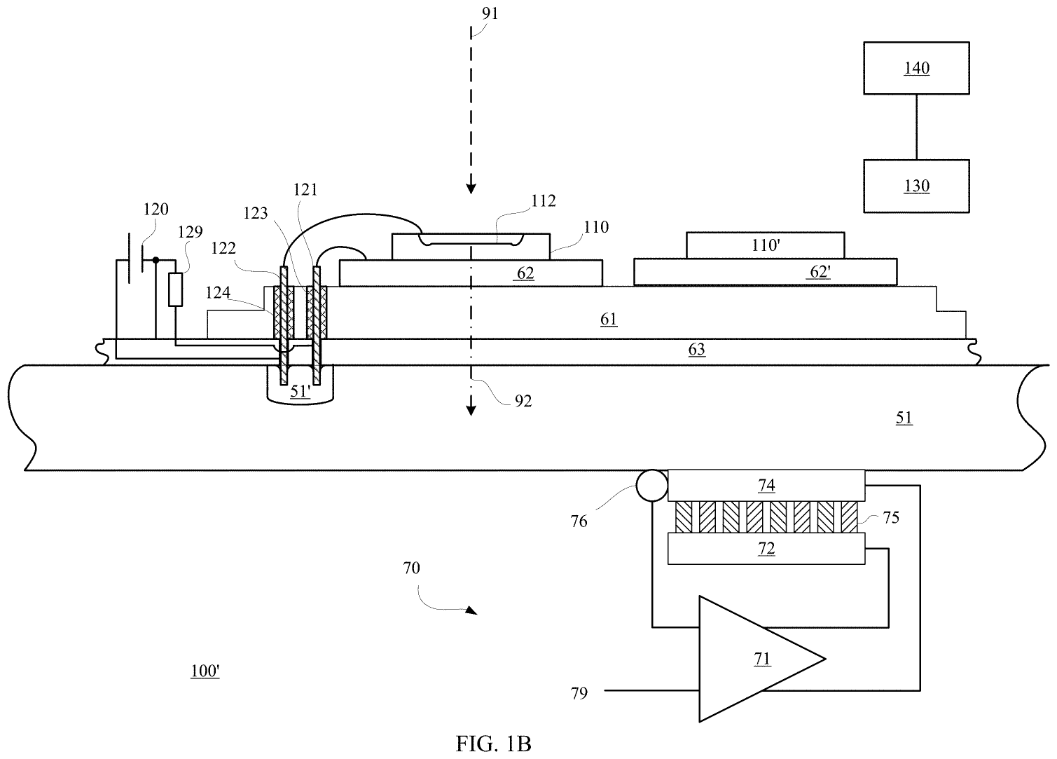

The temperature sensitive component and the solid state photosensor can form a single combined device, or may be separated from each other. An example of a temperature sensitive component that is separated from a solid state photosensor is shown on FIG. 1B.

The measurement result may be indicative of a temperature of the junction at a point of time in which the junction is not heated. The measurement can be made at a point of time that is proximate enough to a heating of the junction so that the measured temperature is substantially the same to the temperature of the junction during the heating.

The measurement result may be indicative of a temperature of the junction at a point of time in which the junction is heated.

FIG. 1A illustrates a detection circuit 100 that includes a solid state photosensor 110 that includes a junction 112, an electrical insulator 62, a base 61, a bias circuit 120, a load 129, a controller 130, a measurement circuit 140, a temperature controlling element 70, intermediate plate 51, and printed circuit board (PCB) 63. Intermediate plate 51 may be mechanically (thermally) connected to base 61 directly, for example through opening in the printed circuit board 63.

Measurement circuit 140 is configured to measure or estimate a forward junction voltage in any manner illustrated in the application. It should be noted that the measurement circuit may measure any other parameter related to the temperature of the junction. Examples of other ways to measure any other parameter related to the temperature of the junction are illustrated above. The measurement circuit may include a voltmeter and/or a current meter, and/or a heat sensor, or any other measurement unit.

The measurement circuit 140 may be configured to measure the forward junction voltage while the junction is not heated. In this case the measurement can be made at a point of time that is proximate enough to a heating of the junction so that the measured temperature is substantially the same to the temperature of the junction during the heating.

The measurement circuit 140 may be configured to measure the forward junction voltage while heating the junction.

Controller 130 that is configured to control the temperature of the junction of the solid state photosensor based on the measured or estimated forward junction voltage. The control of the temperature can be done in any manner illustrated in the application.

It is assumed, for brevity of explanation, that controller 130 is configured to control the temperature based on the forward junction voltage at pre-defined value of the forward current and a relationship between (i) a temperature of the junction and (ii) a forward junction voltage developed over the junction at pre-defined value of the forward current. It should be noted that the controller 130 may control the temperature in any manner of the illustrated in the application. Examples of other ways to control the temperature of the junction are illustrated in various locations in the specification.

The intermediate plate 51 is located above the temperature controlling element 70 and below the PCB 63. The base 61 is positioned above the PCB 63 and below the electrical insulator 62. The solid state photosensor 110 is positioned above the electrical insulator 62.

The temperature controlling element 70 may be used for keeping the junction temperature stable and at required value during normal operation. Controller 130 may be used for heating the junction during a curing period. It should be noted that according to an embodiment of the disclosure the temperature controlling unit 70 may function as the controller 130.

The bias circuit 120 is coupled via load 129 to first electrode 121 and is also coupled to second electrode 122. First electrode 121 and second electrode 122 are electrically coupled to the upper end and the lower end of the solid state photosensor 110.

FIG. 1A illustrates that the first electrode 121 and the second electrode 122 are surrounded by electrode insulators 123 and 124 respectively. The first electrode 121, and the second electrode 122 are coupled, through PCB 63, to a bias supply and a photosensor load (not shown).

The temperature controlling element 70 may be a Peltier device that include a hot plate 72, a cold plate 74, semiconductor elements 75 coupled between the hot plate 72 and the cold plate 74, a differential amplifier 71, a temperature sensor 76. The differential amplifier receives a required temperature instruction 79 and controls the temperature of the temperature controlling element's cold plate 74 to obtain the required temperature. An example of temperature controlling element 70 is illustrated in U.S. patent application 2016/0076938, assigned to Applied Materials Inc., which is incorporated herein by reference.

The temperature controlling element 70 may be used to heat or cool plate 51. The roles of the hot plate and the cold plate may be reversed.

FIG. 1A also illustrates an example of a path of photons 91 that impinge on the solid state photosensor 110, and a heat flow 92 from the solid state photosensor 110 towards the plate 51.

The controller 130 may be configured to calculate or receive a relationship between (i) a temperature of the junction and (ii) a forward junction voltage developed over the junction. The relationship is relevant to a scenario in which the junction is forward biased by the bias circuit and a bias forward current that has a predefined value flows through the junction.

The measurement circuit 140 is configured to measure the forward junction voltage, during a curing period and while the bias circuit supplies a bias forward current that flows through the junction and has the predefined value, to provide a measurement result.

The controller 130 is also configured to (i) determine an estimated temperature of the junction based on (a) the relationship, and (b) the measurement result, and (ii) control a heating of the junction based on the estimated temperature of the junction.

The control of the temperature may include tuning the heating to obtain a desired temperature of the junction.

The control scheme is based on the temperature of the junction and is more accurate that control schemes that are not related to a property of the solid state photosensor itself.

The solid state photosensor may be positioned on a support unit and the thermal resistance of a path between the solid state photosensor and the support unit may be low.

The low thermal resistance requires a feedback based control of the curing process—and the feedback based control is provided by mentioned above device.

The heating element is thermally coupled to the solid state photosensor but the temperature of the solid state photosensor may differ from the temperature of the heating elements. Controlling the heating of the junction based on the temperature of the heating element is less accurate than controlling the heating based on the forward junction voltage of the solid state photosensor.

FIG. 1B illustrates a detection circuit 100′ that includes a temperature sensitive component 110′, A solid state photosensor 110 that includes a junction 112, an electrical insulator 62, a base 61, an additional electrical insulator 62′, a bias circuit 120, a load 129, a controller 130, a measurement circuit 140, a temperature controlling element 70, intermediate plate 51, and printed circuit board (PCB) 63. Intermediate plate 51 may be mechanically (thermally) connected to base 61 directly, for example through opening in the printed circuit board 63.

The base 61 is positioned above the PCB 63 and below the electrical insulator 62 and the additional electrical insulator 62′. The solid state photosensor 110 is positioned above the electrical insulator 62. The temperature sensitive component 110′ is positioned above the additional electrical insulator 62′.

The temperature sensitive component 110′ is thermally coupled to the solid state photosensor 110 via base 61.

The measurement circuit 140 may measure a temperature related parameter of the temperature sensitive component 110′ and determine the measurement result based on the temperature related parameter.

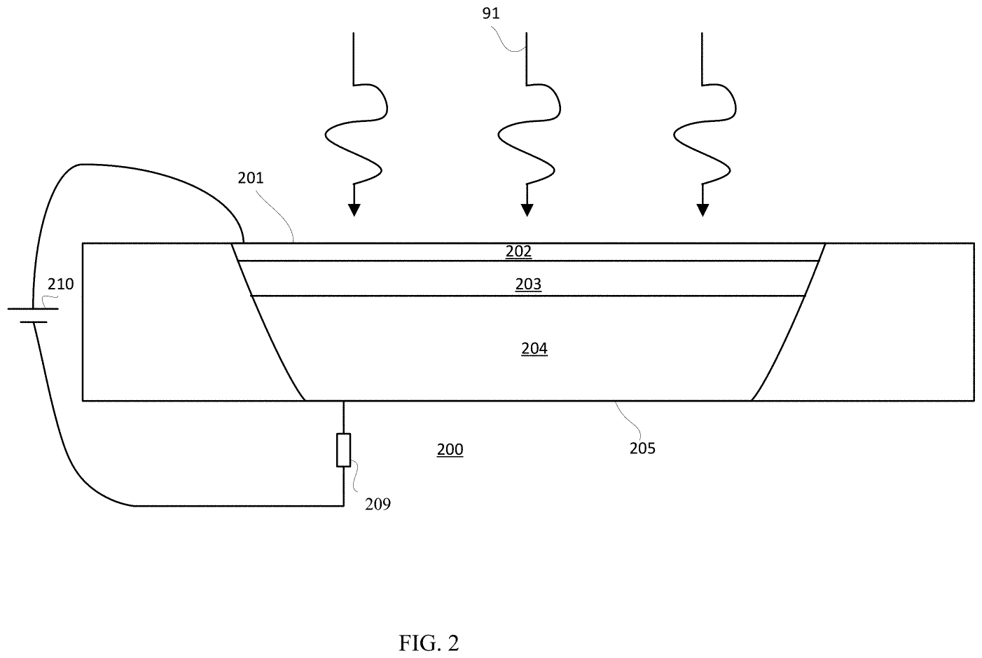

FIG. 2 is an example of a PIN diode 200, bias circuit 210 and load 209.

The PIN diode 200 is an example of a solid state photosensor 110 of FIG. 1A.

Bias circuit 210 biases the junction of the PIN diode 200 through load 209. The polarity of the bias circuit may be opposite to the polarity illustrated in FIG. 2.

There is a first electrical contact 201 at the top of PIN diode 200. It may be formed on an upper surface of an N type semiconductor region 202. The N type semiconductor region 202 is positioned above an absorption region 203 that is positioned above a P type semiconductor region 204. A second electrical contact 205 is formed at the bottom of the PIN diode 200. The absorption region 203 may be an intrinsic region.

The first electrical contact 201 and the second electrical contact 205 are electrically coupled to the bias circuit 210 and load 209.

The order of the regions of the PIN diode 200 may be reversed. Accordingly—the N type semiconductor region 202 may be positioned below the absorption region 203, and the absorption region 203 may be positioned below the P type semiconductor region 204.

The junction of the PIN diode 200 refers to a potential barrier created by applying a reverse bias voltage depleting a certain volume of the PIN diode 200. The junction may include at least a part of the N type semiconductor region 202, the absorption region 203, and at least a part of the P type semiconductor region 204.

The curing process may cure damages that occur in the upper layer (in FIG. 2 it is the N type semiconductor region 202) and damages that occur in the absorption region 203.

It should be noted that the upper region may be a P type semiconductor, and the lower region can be a N type semiconductor. In this case the polarity of the bias circuit 210 will be reversed and a signal current will flow in opposite direction.

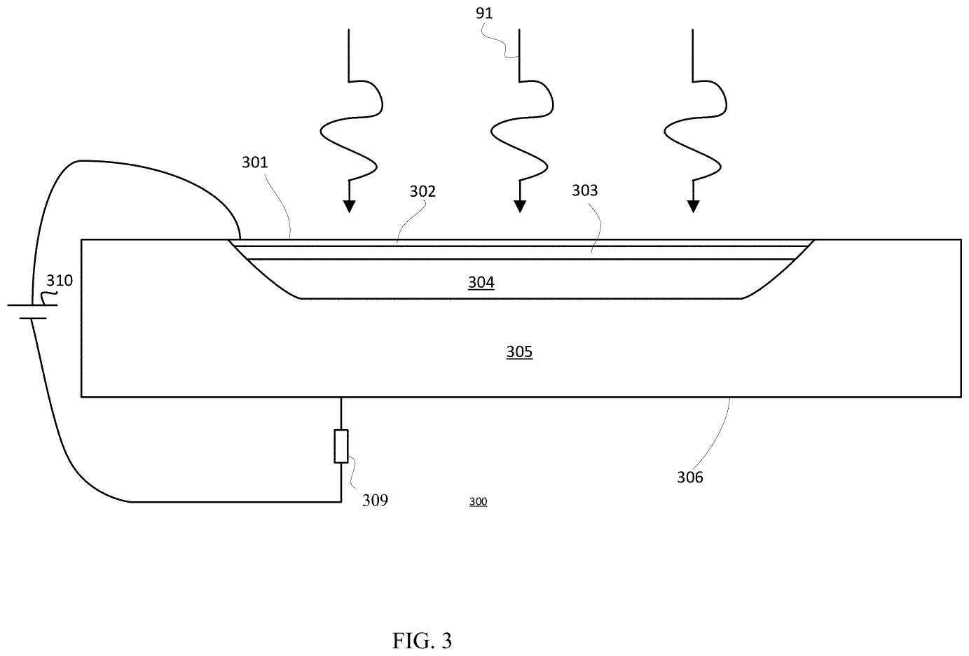

FIG. 3 is an example of an avalanche photodiode (APD) 300 and a bias circuit 310 and a load 309.

The APD 300 is an example of a solid state photosensor 110 of FIG. 1A.

Bias circuit 310 biases the junction of the APD 300 through load 309. The polarity of the bias circuit may be opposite to the polarity illustrated in FIG. 3.

There is a first electrical contact 301 at the top of APD 300. It may be formed on an upper surface of an absorption region 302. The absorption region 302 is positioned above a multiplication region 303 that is positioned above a collection region 304. The collection region 304 is positioned above bulk 305.

A second electrical contact 306 is formed at the bottom of the bulk 305.

The first electrical contact 301 and the second electrical contact 306 are electrically coupled to the bias circuit 310 and the load 309.

The junction of the APD 300 refers to a potential barrier, made by applying a reverse bias voltage and depleting certain volume of the APD 300. The junction may include at least a part of the absorption region 302, multiplication region 303 and the collection region 304.

The curing process may cure damages that occur in the absorption region 302 and damages that occur in the multiplication region 303.

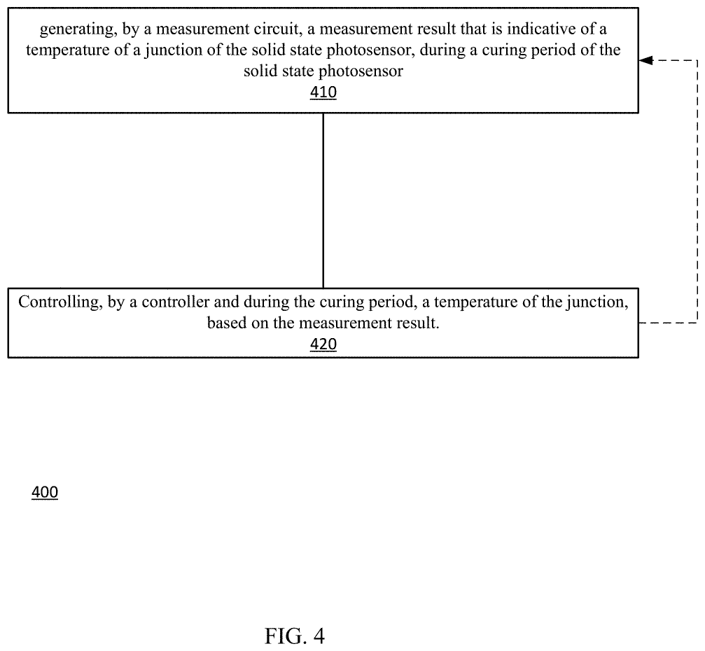

FIG. 4 is an example of a method 400.

Step 410 may include generating, by a measurement circuit, a measurement result that is indicative of a temperature of a junction of the solid state photosensor during a curing period of the solid state photosensor.

Step 410 may include at least one out of:
a. Measuring, by the measurement circuit, a forward junction voltage developed over the junction during the curing period, and determining the measurement result based on the forward junction voltage.
   i. The determining may be based on a relationship between (i) a temperature of a junction of the solid state photosensor and (ii) a forward junction voltage developed over the junction while the junction is forward biased and a bias forward current that has a predefined value flows through the junction. The relationship may be calculated during method 420 or received during method 400.
b. Measuring, by the measurement circuit, heat radiation emitted from the solid state photosensor, and determining the measurement result based on the heat radiation.
c. Measuring, by the measurement circuit, during the curing period, a temperature related parameter of a temperature sensitive component that is thermally coupled to the solid state photosensor, and determining the measurement result based on the temperature related parameter. The temperature sensitive component may be a thermistor, may be positioned above the same base as the solid state photosensor, may be positioned above another base, may be incorporated inside the solid state photoresistor, may be integrated with the solid state photoresistor, and the like.

Step 410 may be followed by step 420 of controlling, by a controller and during the curing period, a temperature of the junction, based on the measurement result.

Step 420 may include at least one out of:
a. Controlling a flow of forward current through the junction.
b. Controlling temperature determining element that is thermally coupled to the solid state photosensor.
c. Controlling an illumination of the junction.

Multiple repetitions of steps 410 and 420 may be performed during a single curing period. This is illustrated in FIG. 4 by a dashed arrow from step 420 to step 410.

Step 410 may be executed while the junction is heated.

Step 410 may be executed during gaps in a heating of the junction. The gaps may be shorter than the curing period—for example less than 1, 5, 10, 15, 20, 25 percent of a duration of the curing period.

During the curing period, the heating may be executed in multiple non-consecutive heating iterations and step 410 may be executed after a non-consecutive heating iteration, or during a gap between two consecutive heating iterations of the curing period.

The gap between heating iterations may be small enough not to substantially reduce an effectiveness of the curing process. And may be long enough to still accurately measure the temperature of the junction as it substantially was while being heated.

The gap may be long enough to allow the measurement of the forward junction voltage.

Step 410 be executed after a completion of a forward junction voltage stabilization period from a start of a gap.

The heating may include illuminating the solid state photosensor. The solid state photosensor will generate a detection current that in turn may heat the junction.

The heating may include flowing through the junction the bias forward current of a value that exceeds the predefined value. The value of the bias forward current during the heating may be referred to heating value. The heating value may exceed by at least a factor of 5, 10, 20, 50 and even more than the predefined value.

The heating may be performed using a heating element that is thermally coupled to the solid state photosensor. The heating element may be a thermoelectric cooler or any other heating element.

In the foregoing specification, the embodiments of the disclosure has been described with reference to specific examples of embodiments of the disclosure. It will, however, be evident that various modifications and changes may be made therein without departing from the broader spirit and scope of the embodiments of the disclosure as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to be a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to embodiments of the disclosure s containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments of the disclosure have been illustrated and described herein, many modifications, substitutions, changes, and equivalents will now occur to those of ordinary skill in the art. It is, therefore, to be understood that the appended claims are intended to cover all such modifications and changes as fall within the true spirit of the embodiments of the disclosure

We claim:

1. A detection circuit that comprises:
a solid state photosensor that comprises a junction;
a controller; and
a measurement circuit;
wherein the measurement circuit is configured to generate a measurement result that is indicative of a temperature of the junction during a curing period of the solid state photosensor; and
wherein the controller is configured to control, during the curing period, the temperature of the junction, based on the measurement result.

2. The device according to claim 1, wherein the measurement circuit is configured to (a) measure a forward junction voltage developed over the junction during the curing period, and (b) determine the measurement result based on the forward junction voltage.

3. The device according to claim 1, wherein the measurement circuit is configured to (a) measure heat radiation emitted from the solid state photosensor, and (b) determine the measurement result based on the heat radiation.

4. The device according to claim 1, wherein the measurement circuit is configured to (a) measure, during the curing period, a temperature related parameter of a temperature sensitive component that is thermally coupled to the solid state photosensor, and (b) determine the measurement result based on the temperature related parameter.

5. The device according to claim 1 wherein the measurement result is indicative of a temperature of the junction at a point of time in which the junction is not heated.

6. The device according to claim 1 wherein the measurement result is indicative of a temperature of the junction at a point of time in which the junction is heated.

7. The device according to claim 1 wherein the controller is configured to control the temperature of the junction by controlling an illuminating of the junction, by an illumination source, during the curing period.

8. The device according to claim 1 wherein the controller is configured to control the temperature of the junction by controlling a flow of forward current through the junction.

9. The device according to claim 1 wherein the controller is configured to control the temperature of the junction by controlling a temperature determining element that is thermally coupled to the solid state photosensor.

10. A method for curing a solid state photosensor, the method comprises:
generating, by a measurement circuit, a measurement result that is indicative of a temperature of a junction of the solid state photosensor, during a curing period of the solid state photosensor; and
controlling, by a controller and during the curing period, a temperature of the junction, based on the measurement result.

11. The method according to claim 10, comprising measuring, by the measurement circuit, a forward junction voltage developed over the junction during the curing period, and determining the measurement result based on the forward junction voltage.

12. The method according to claim 10, comprising measuring, by the measurement circuit, heat radiation emitted from the solid state photosensor, and determining the measurement result based on the heat radiation.

13. The method according to claim 10, comprising measuring, by the measurement circuit and during the curing period, a temperature related parameter of a temperature sensitive component that is thermally coupled to the solid state photosensor, and determining the measurement result based on the temperature related parameter.

14. The method according to claim 10, comprising controlling the temperature of the junction by controlling a flow of forward current through the junction.

15. The method according to claim 10, comprising controlling the temperature of the junction by controlling a temperature determining element that is thermally coupled to the solid state photosensor.
